(19) United States
(12) Patent Application Publication
(10) Pub. No.: US 2010/0187095 A1
(43) Pub. Date: Jul. 29, 2010

(54) MANUFACTURING METHOD OF A BORIDE FILM, AND MANUFACTURING METHOD OF AN ELECTRON-EMITTING DEVICE

(75) Inventors: Naofumi Aoki, Chigasaki-shi (JP); Tomoyasu Mizuno, Hiratsuka-shi (JP); Tamaki Kobayashi, Isehara-shi (JP); Yusuke Miyamoto, Atsugi-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/691,454

(22) Filed: Jan. 21, 2010

(30) Foreign Application Priority Data
Jan. 29, 2009 (JP) 2009-018344

(51) Int. Cl. C23C 14/46

(52) U.S. Cl. 204/192.11

(57) ABSTRACT

A boride film is deposited on a substrate through an opening portion a shield member located between the substrate and a target by means of a sputtering method. The shield member is arranged so as to shield between an erosion region of the target and the substrate. A distribution of plasma density in a space between the substrate and the target is set in such a manner that a plasma density in a region in which the opening portion is located becomes higher than a plasma density in a region shielded by the shield member.

### BACKGROUND OF THE INVENTION

1. Field of the Invention

The present invention relates to a production method of a boride film using a sputtering method, and a production method of an electron-emitting device.

2. Description of the Related Art

A field emission type electron-emitting device is an electron-emitting device of the type that applies a voltage (electric field) across a cathode electrode (and an electron emission structure arranged thereon) and a gate electrode, and pulls out electrons into a vacuum from a cathode electrode side by means of this voltage (electric field). Therefore, the operating electric field is greatly influenced by the work function, shape, etc., of the cathode electrode (electron emission structure) to be used. Theoretically, it is considered that the smaller the work function of the cathode electrode (electron emission film), with the lower operating voltage the cathode electrode can be driven. In Japanese patent application laid-open No. H01-235124 and U.S. patent Serial No. 4008412, there is disclosed an electron-emitting device that has a lanthanum hexaboride (LaB₆) film as an electron-emitting member of a low work function coated on an electron emission structure (Spindt, etc.) made of metal. In addition, in Japanese patent application laid-open No. 2000-173365 and Japanese patent application laid-open No. 2001-270795, there are disclosed a sputtering method and a sputtering system.

### SUMMARY OF THE INVENTION

In producing an electron-emitting device using a lanthanum boride film, it is preferable, from the viewpoint of the stability of electron emission, etc., that the film has higher crystallinity. In addition, in the orientation of crystals, an orientation to a (100) surface among other orientations serves to stabilize electron emission. This is because the (100) surface has less surface dangling bonds as compared with a (110) surface or a (111) surface, and has lower impurity adsorption capacity.

However, according to a study of the present inventors, it was proved that in the deposition of a film by means of a sputtering method, the crystallinity and orientation of a lanthanum boride film are greatly changed by a difference in the film deposition condition.

FIG. 6A is a layout view of a parallel plate type sputtering apparatus that has been well known in the past. 501 denotes a substrate holder, 502 a substrate, and 503 a cathode. The cathode 503 is composed of a target 505, a backing plate 506, a magnet 507, and a yoke 508. A magnetic field is generated by the magnet 507, as represented by magnetic lines of force 509, and 504 denotes an erosion region. With the use of such an apparatus, lanthanum boride was deposited to a thickness of 50 nm on a Si wafer substrate to form a film while using an 8-inch circular member of lanthanum hexaboride as a target and the Si wafer substrate as a substrate 502, by holding the temperature of the substrate at room temperature, and by supplying Ar so as to provide a total pressure of 1.5 Pa. RF electric power supplied to the target was 500 W, and the distance between the target and the substrate was 90 mm. By analyzing the lanthanum boride film deposited as a result thereof by means of an X-ray diffraction method, and by reorganizing the relation between the full width at half maximum (FWHM) of a diffraction peak on the (100) surface and the position of the substrate, the following result was obtained as shown in FIG. 6B. The smaller the FWHM, the larger the crystallite size of crystals becomes, thus showing good crystals. With respect to the position of the substrate, the distance thereof from the center of the target illustrated in FIG. 6A is shown. As shown in FIG. 6B, at a position in opposition to the erosion region, the FWHM is large, and on the other hand, as the substrate position moves away from the position in opposition to the erosion region, the FWHM becomes smaller. That is, it was found that the film quality varies and the crystallinity of the lanthanum boride film becomes low at the position in opposition to the erosion region. As a result of a further study, it turned out that even if the distribution of plasma density is changed by changing the magnetic field of the magnet, the crystallinity of that portion of the lanthanum boride film which is in opposition to the erosion region is always low. That is, it was found that the film quality has stronger correlation with the position of the erosion region rather than the plasma density distribution. Hereinafter, the region (or position) which is in opposition to the erosion region is called an erosion opposed region (or position). In addition, a region which is not the erosion region is called a non-erosion region, and a region (or position) which is in opposition to the non-erosion region is called a non-erosion opposed region (or position).

The cause for the fact that the crystallinity of a film decreases in an erosion opposed position when a lanthanum boride target is used is not clear, but according to the study of the present inventors, it was found that a position dependency of the film quality exists at least in sputtering using a lanthanum boride target. On the other hand, in cases where an electron-emitting device is used for an electron source of an image display device, it is desirable to deposit a lanthanum boride film on a substrate of a large size as homogeneously as possible. Accordingly, in order to ease the position dependency of the film quality, a so-called moving deposition is performed in which the deposition of a film is carried out while moving a substrate and a target relatively to each other. In the moving deposition, a film deposited part (electron-emitting device) on the substrate passes through both of the erosion opposed region and the non-erosion opposed region. When a position dependency of film quality was large at this time, it was difficult to produce a lanthanum boride film of good crystallinity with a (100) surface oriented.

As a method for preventing the damage of a film in an erosion opposed region due to oxygen anions at the time of using an oxide target instead of a lanthanum boride target, there has been known the arrangement of a shield plate (Japanese patent application laid-open No. 2000-173365, and Japanese patent application laid-open No. 2001-270795). However, it is difficult to produce a lanthanum boride film of good crystallinity according to this method.

The result of a study of the present inventors about the arrangement of a shield plate will be described. According to the inventors, a shield plate was arranged in a space between a target and a substrate in a manner to hide an erosion opposed region, and the sputtering deposition of lanthanum boride was performed. However, as a result, a film of good crystallinity with the effect of a shield plate exerted thereon was not able to be obtained. This is due to the possibility that plasma might be disturbed by the arrangement of the shield plate, thus causing a shortage of deposition energy. Even if the sputtering gas pressure and/or sputtering power were regulated, the crystallinity of the film was not able to be improved. Here, note that the same problem as stated above was also seen in sputtering using a boride target other than a lanthanum boride target.

The present invention has been made in view of the above-mentioned actual circumstances, and has for its object to provide a technique which produces a boride film of good crystallinity by improving a variation in film quality in a sputtering method. Another object of the present invention is to provide a technique which forms a boride film of homogeneous film quality (crystallinity) on a substrate of a large area. In addition, a further object of the present invention is to provide a production method of an electron-emitting device which is excellent in an electron emission characteristic (in particular, the stability of electron emission). Moreover, a still further object of the present invention is to provide a technique for improving the decrease in deposition energy due to the arrangement of a shield member with a simple construction.

The present invention in its first aspect provides a manufacturing method of a boride film, comprising the steps of: preparing a substrate, a target of a boride, and a shield member having an opening portion; and depositing a boride film on the substrate through the opening portion by means of a sputtering method in a state where the substrate, the target and the shield member are arranged in such a manner that the substrate and the target are arranged in opposition to each other, with the shield member being positioned between the substrate and the target, wherein the shield member is arranged so as to shield between an erosion region of the target and the substrate; and a distribution of plasma density in a space between the substrate and the target is set in such a manner that a plasma density in a region in which the opening portion is located becomes higher than a plasma density in a region shielded by the shield member.

The present invention in its second aspect provides a manufacturing method of a boride film, comprising the steps of: preparing a substrate, a target of a boride, and a shield member; and depositing a boride film on the substrate through a region not shielded by the shield member by means of a sputtering method in a state where the substrate, the target and the shield member are arranged in such a manner that the substrate and the target are arranged in opposition to each other, with the shield member being arranged to shield between an erosion region of the target and the substrate, wherein a distribution of plasma density in a space between the substrate and the target is set in such a manner that a plasma density in the region not shielded by the shield member becomes higher than a plasma density in a region shielded by the shield member.

The present invention in its third aspect provides a manufacturing method of an electron-emitting device provided with a boride film as an electron-emitting member, wherein the boride film is manufactured by means of the above manufacturing method of a boride film.

According to the present invention, it is possible to improve a variation in film quality in a sputtering method thereby to produce a boride film of good crystallinity. In addition, it is possible to form a boride film of homogeneous film quality (crystallinity) on a substrate of a large area. Moreover, it is possible to produce an electron-emitting device that is excellent in the electron emission characteristic (in particular the stability of electron emission). Further, the decrease in deposition energy due to the arrangement of a shield member can be improved with a simple construction.

Further features of the present invention will become apparent from the following description of exemplary embodiments with reference to the attached drawings.

### BRIEF DESCRIPTION OF THE DRAWINGS

FIG. 1 is a schematic diagram of a parallel plate type sputtering apparatus.

FIG. 2A through FIG. 2C are schematic diagrams showing an example of an electron-emitting device.

FIG. 3 is a cross-sectional schematic diagram of a polycrystalline film of lanthanum boride.

FIG. 4A through FIG. 4F are schematic diagrams showing an example of a production method of an electron-emitting device.

FIG. 5 is a schematic diagram of a parallel plate type sputtering apparatus.

FIG. 6A is a conventional schematic diagram of a parallel plate type sputtering apparatus, and FIG. 6B is a view showing the relation between the crystallinity of a lanthanum hexaboride film and the position of deposition thereof.

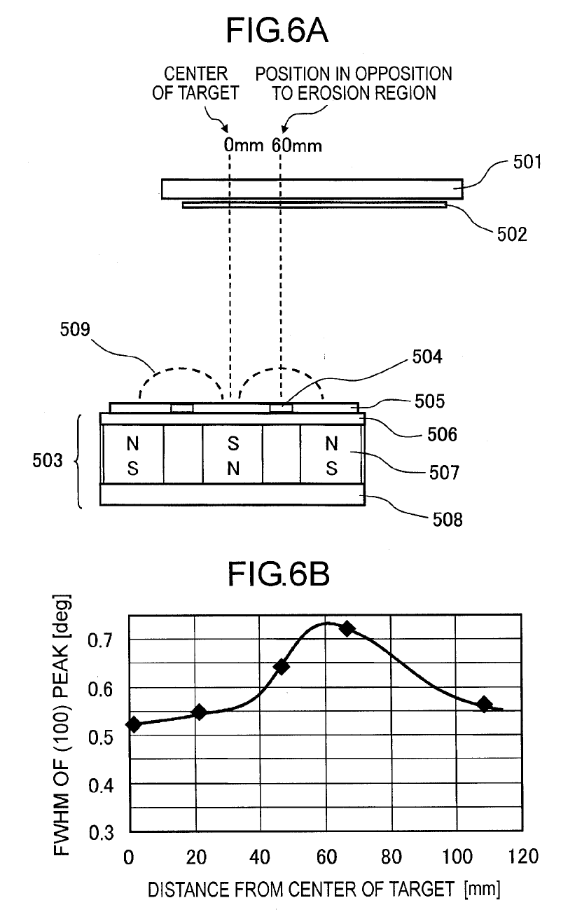

### DESCRIPTION OF THE EMBODIMENTS

Hereinafter, preferred embodiments of this invention will be described with reference to the accompanying drawings. However, the dimensions, materials, shapes, relative arrangements and so on of component parts described in the embodiments are not intended to limit the scope of the present invention to these alone in particular as long as there are no specific statements.

(Sputtering Method)

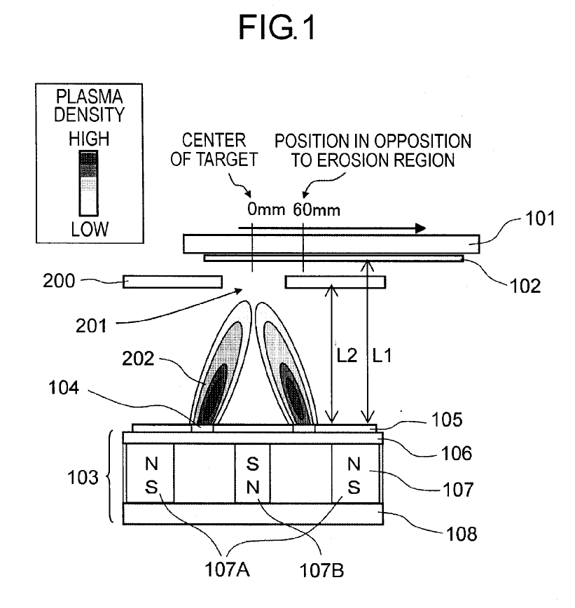

A sputtering apparatus and a sputtering method will be described with reference to FIG. 1. FIG. 1 is a view schematically showing the interior of a chamber of parallel-plate sputtering apparatus. The sputtering apparatus is roughly provided with a substrate holder 101 for holding a substrate 102, and a cathode 103 on which a target 105 is to be installed. The cathode 103 has a backing plate 106, a magnet 107, and a yoke 108. The magnet 107 is composed of an outer magnet 107A of a doughnut shape (ring shape), and an inner magnet 107B that is arranged at the center of the outer magnet 107A, wherein a magnetic field is formed by means of this magnet. By this magnetic field, a single erosion region 104 of a doughnut shape (ring shape) is formed in the target 105.

A shield plate (shield member) 200 having an opening portion 201 is arranged between the substrate 102 and the target 105. The shield plate 200 is arranged in such a manner as to shield between the erosion region 104 of the target 105 and an erosion opposed region of the substrate 102, i.e., so as to shield or interrupt particles flying from the erosion region 104 toward the substrate 102 in a vertical upper direction. It can also be said that the shield plate 200 is arranged so as to hide the erosion opposed region of the substrate 102, or so as to hide the surface of the substrate 102 from the erosion region 104. A distance L2 between the shield plate 200 and the target 105 becomes smaller than a distance L1 between the substrate 102 and the target 105. In order to form a film of good crystallinity, it is desirable that the distance L2 between the shield plate 200 and the target 105 be close to the distance L1 between the substrate 102 and the target 105, i.e., a distance (L1-L2) between the substrate 102 and the shield plate 200 is sufficiently small.

The opening portion 201 of the shield plate 200 is formed at a location other than a region in opposition to the erosion region 104. In an example shown in FIG. 1, the opening portion 201 is formed at a location in opposition to the center of the target 105. At the time of deposition, sputtered particles accumulate on the substrate 102 through this opening portion 201. Here, note that the position, shape, number, etc., of the opening portion can be set in an arbitrary manner without being limited to those in the example shown in FIG. 1. For example, the opening portion is arranged within the erosion region in an example of FIG. 1, but an opening portion can also instead be arranged outside of the erosion region, and opening portions may be arranged both inside and outside, respectively, of the erosion region. In addition, instead of forming a through hole or a notch as an opening portion in a part of the shield plate, only a partial region of a space between the target and the substrate by using a shield plate whose size (area) is smaller than that of the target. In this case, the region other than the partial region shielded or interrupted by the shield plate (i.e., the region which is not shielded or interrupted by the shield plate) can be called an opening portion.

As mentioned above, in cases where a boride is used as a target material, a phenomenon is seen in which the crystallinity of the boride film becomes worse due to the arrangement of the shield plate. This is considered to be due to one of the causes that the deposition energy is decreased by the arrangement of the shield plate.

Consequently, in this embodiment, the decrease in the deposition energy is compensated for by raising a plasma density in the opening portion of the shield plate (the region which is not shielded or interrupted by the shield plate) higher than that in the other region. In order to achieve such a plasma density distribution, the plasma is caused to concentrate on a region in which the opening portion is located, by raising the density of magnetic flux in that region in which the opening portion is located higher than that in the region shielded or interrupted by the shield plate, by using a magnetic field generation device such as a permanent magnet, an electromagnet or the like. At this time, it is preferable from a view point of the simplification of construction that a magnet 107 of a cathode 103 also serves as the magnetic field generation device for controlling the distribution of plasma density. However, the magnetic field generation device for the control of the distribution of plasma density can also be formed separately from the magnet 107 (e.g., at a shield plate side).

In the example of FIG. 1, the magnet 107 is composed of a convergence type magnet which is designed so that a magnetic flux density in a central portion of the target becomes higher than that in a peripheral edge portion thereof. It is possible to regulate the balance of magnetic flux density and the distribution of plasma density by setting the magnetic forces, shapes, arrangement, etc., of an outer magnet 107A and an inner magnet 107B in an appropriate manner. For example, with the magnet 107 of FIG. 1, the width of the inner magnet 107B is smaller than that of the outer magnet 107A. According to this, the magnetic flux density in the central portion of the target becomes higher than that in the other portion thereof, so the plasma density in the opening portion 201 of the shield plate 200 becomes higher than that in the other portion thereof, as shown by a plasma density distribution 202.

After vacuum drawing the interior of the chamber to a vacuum pressure of 2×10⁻⁴ Pa or less by the use of a high vacuum exhaust pump, deposition or film formation is carried out by introducing a sputtering gas into the chamber, holding it at a predetermined pressure, and applying electric power to the cathode 103. Although an argon (Ar) gas, a krypton (Kr) gas, a xenon (Xe) gas, or the like can be used as the sputtering gas, it is in particular desirable to use an argon gas from the point of view of manufacturing costs. As a sputtering power source, a DC power supply or an RF power supply of an industrial power supply frequency such as 13.56 MHz is used.

In this sputtering apparatus, the target 105 and the substrate 102 are arranged in opposition to each other, and the substrate 102 and the target 105 are relatively moved with respect to each other by conveying or moving the substrate 102 in an arrow direction in FIG. 1 at the time of deposition (moving deposition). At the time when the substrate 102 passes through the opening portion 201 of the shield plate 200, a film of the target material is formed on the surface of the substrate 102. Here, note that the target 105 alone may be conveyed, or both the substrate 102 and the target 105 may be conveyed. In addition, not only a translational movement but also a rotational movement may be employed.

As the target material, there can be used borides such as for example HfB₂, ZrB₂, LaB₆, CeB₆, YB₄, GdB₄ and so on.

According to the method as described above, the decrease of crystalline in the erosion opposed region can be prevented by the arrangement of the shield plate 200. In addition, the amount of ions (e.g., Ar ions in the case of an argon gas) irradiated to the substrate 102 is increased by making the plasma density in the opening portion 201 higher. These ions provide energy to the atoms deposited on the substrate 102, so a boride film of good crystalline can be obtained.

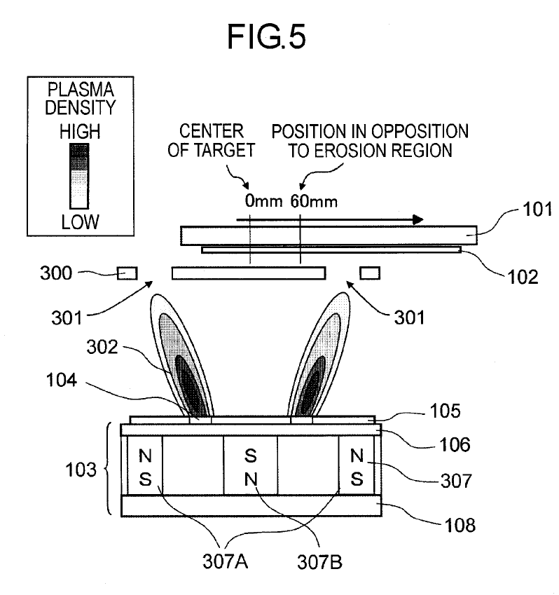

FIG. 5 shows another construction example of a sputtering apparatus. In the example of FIG. 5, the construction of a shield plate (shield member) and a magnet (magnetic field generation device) is different from that of FIG. 1. Specifically, a shield plate 300 of FIG. 5 has an annular opening 301 outside of an erosion region 104. In addition, a magnet 307 is composed of a divergence type magnet which is designed so that a magnetic flux density in a peripheral edge portion of a target becomes higher than that in a central portion thereof. The magnet 307 is constructed such that the width of an inner magnet 307B is larger than that of an outer magnet 307A. According to this, the magnetic flux density in the peripheral edge portion of the target becomes higher than that in the other portion thereof, so a plasma density in an opening portion 301 of the shield plate 300 becomes higher than that in the other portion thereof, as shown by a plasma density distribution 302. In this construction, too, a film of good crystalline can be formed as in FIG. 1.

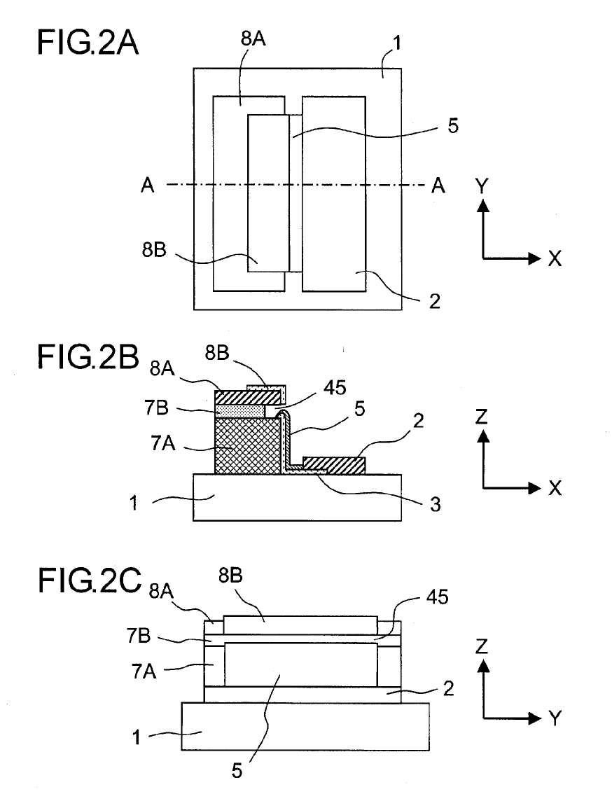

Next, reference will be made to a manufacturing method of a field emission type electron-emitting device provided with a lanthanum boride film produced according to this embodiment while using FIG. 2A, FIG. 2B and FIG. 2C. FIG. 2A is a plan schematic diagram looking at the electron-emitting device from a direction of Z, and FIG. 2B is a cross-sectional (Z-X surface) schematic diagram taken on line A-A in FIG. 2A. FIG. 2C is a schematic diagram looking at FIG. 2A from a direction of X.

In this electron-emitting device, a gate electrode 8A is formed on a substrate 1 through a first insulating layer 7A and a second insulating layer 7B. In addition, a cathode electrode 2 is formed on the substrate 1, and an electron emission structure (conductive film) 3 connected to the cathode electrode 2 extends toward a direction away from the substrate 1 along a side wall of the first insulating layer 7A. In the direction of X, the second insulating layer 7B is smaller in width than the first insulating layer 7A, and a recess 45 is formed between the first insulating layer 7A and the gate electrode 8A. Moreover, as is clear from FIG. 2B, the above-mentioned electron emission structure 3 projects in the direction of Z more than an upper surface of the first insulating layer 7A. That is, the electron emission structure 3 is provided with a protruded portion protruding in a direction near to the gate electrode 8A from the upper surface of the first insulating layer 7A. In addition, a part of the electron emission structure 3 comes in the recess 45. As a result, it can be said that the electron emission structure 3 is provided with the protruded portion that is formed on a surface of the insulating layer 7A located in the recess 45. Electrons are mainly emitted from this protruded portion.

In addition, FIG. 2B shows an example in which a part of the gate electrode 8A is covered with a conductive film 8B of the same material as the electron emission structure 3. This conductive film 8B can also be omitted, but in order to form a stable electric field, it is preferable to provide the conductive film 8B. As a result, in the example shown in FIG. 2B, the gate electrode is composed of the members denoted by 8A and 8B.

The electron emission structure 3 is covered with a lanthanum boride film (preferably, a lanthanum hexaboride film) 5 which serves as an electron-emitting member. This lanthanum boride film 5 is deposited by the above-mentioned sputtering method. In the example of FIG. 2B, the entire electron emission structure 3 is covered with the lanthanum boride film 5, but at least the surface of the protruded portion of the electron emission structure 3 should just be covered with the lanthanum boride film 5.

It is preferable that the lanthanum boride film 5 be a poly-crystalline film of lanthanum boride rather than a single-crystalline film thereof. As compared with the single-crystalline film, the poly-crystalline film can be more easily deposited and is more stable because it can cover the electron emission structure 3 along its surface of a complicated shape with fine irregularities and can also make the internal stress thereof lower. Here, note that the single-crystalline film is lower in work function than the poly-crystalline film, but it is also possible even for the poly-crystalline film to obtain a work function lower than 3.0 eV, which is near to that of the single-crystalline film, by controlling the film thickness and the crystallite size of the film.

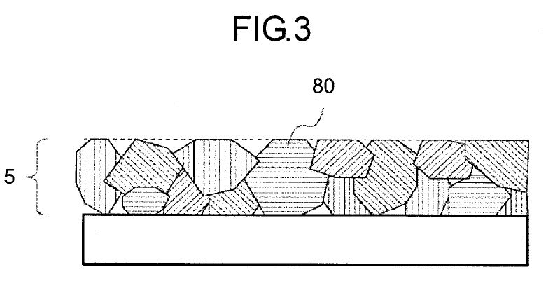

The polycrystalline film of lanthanum boride is provided with conductivity. The polycrystalline film 5 of lanthanum boride in this embodiment exhibits metallic conduction. As shown in FIG. 3, the polycrystalline film 5 of lanthanum boride according to this embodiment has a special feature as a so-called polycrystalline substance composed of a large number of crystallites 80. Each of the crystallites 80 is composed of lanthanum boride. A crystallite means the greatest assembly that can be regarded as a single crystal. Here, note that the poly-crystalline film 5 indicates a film in which the crystallites 80 are joined (placed in abutment) with one another or a plurality of lumps (aggregates) of crystallites are joined (placed in abutment) with one another to exhibit metallic conductivity, and it differs from a so-called fine particle film that is made of an aggregate of fine particles.

The poly-crystalline film 5 may be constructed such that the crystallites 80 are joined with one another or a plurality of lumps (aggregates) of crystallites are joined with one another, with voids (gaps or spaces) existing among the crystallites 80 or among the plurality of lumps (aggregates) of crystallites.

The crystallites 80 forming the polycrystalline film 5 of lanthanum boride in this embodiment each have a size equal to or larger than 2.5 nm, and the polycrystalline film 5 has a film thickness of 100 nm or less. Therefore, an upper limit of the size of the crystallites 80 forming the polycrystalline film 5 is necessarily set to 100 nm. With a poly-crystalline film having a crystallite size of equal to or larger than 2.5 nm, an emission current is stabilized (i.e., decreased in fluctuation) as compared with a poly-crystalline film having a crystallite size of less than 2.5 nm. In addition, if the crystallite size exceeds 100 nm, the film thickness of the poly-crystalline film will exceed 100 nm, as a result of which film peeling will occur to a remarkable extent, and hence, if such a film is used for an electron-emitting device, the element will have an unstable characteristic. If the film thickness of the poly-crystalline film is smaller than 2.5 nm, a work function will become larger than 3.0 eV. This is considered to be due to the fact that the composition ratio of La and B deviates greatly from 6.0, resulting in an unstable state where the poly-crystalline film becomes impossible to maintain its crystallinity. In addition, in particular, it is preferable that the film thickness be equal to or less than 20 nm, because the variation of the electron emission characteristic under such a condition is small.

The crystallite size can be typically calculated from X-ray diffraction measurements. Specifically, it can be calculated from the profile of a diffraction line by means of a method called a Scherrer method. The X-ray diffraction measurements can be used not only for the calculation of the crystallite size, but also for the investigation of the structure of the poly-crystalline film 5 composed of poly-crystals of lanthanum hexaboride, and the orientation thereof. Lanthanum hexaboride (LaB₆) has a structure that is represented by the ratio of La and B denoted by 1:6 as the stoichiometric composition thereof, and indicates those which have a simple cubic lattice (however, with respect to the composition ratio, non-stoichiometric compositions can also be included, and those which have lattice constants changed are included, too). In addition, when an observation by means of a cross-sectional TEM (transmission electron microscope) is carried out, a plurality of checked patterns which are seen substantially in parallel with one another are observed or recognized in regions corresponding to the crystallites. Consequently, two checked patterns most away from each other are selected from the se plurality of checked patterns, the length of the longest line segment among line segments each connecting between an end of one checked pattern and an end of the other checked pattern can be recognized as a crystallite size (a crystallite diameter). If a plurality of crystallites are recognized in a region observed by the cross-sectional TEM, an average value of the crystallite sizes of those crystallites can be made as the crystallite size of the poly-crystalline film of lanthanum boride.

In addition, for the measurement of a work function, there are photoelectron spectroscopy such as vacuum UPS, a Kelvin method, a method of deriving a work function from a relation between an electric field and a current by measuring a field emission current in vacuum, etc., and it is also possible to calculate a work function by using them in combination.

A film (metal film) of a thickness of bout 20 nm, made of a material such as for example Mo of which the work function is known, is formed on a surface of a sharp protruded portion of a conductive needle (made of tungsten), and the electron emission characteristic of the film is measured by applying an electric field to the film in a vacuum. Then, a field enhancing factor due to the shape of the protruded portion in the form of a tip of the needle is calculated beforehand from the electron emission characteristic, and thereafter, the poly-crystalline film 5 of lanthanum boride is formed, so that the work function thereof can be obtained by calculation.

The fluctuation of an emission current emitted from the electron-emitting device indicates the magnitude of the temporal change of the emission current. It is, for example, the change of a current emitted by periodic application of a pulsed voltage of a rectangular waveform, and can be calculated by representing the magnitude of the change per unit time with a deviation, and then dividing the deviation by the average value.

Specifically, a pulsed voltage of a rectangular waveform having a pulse width of 1 ms and a frequency of 60 Hz is applied. Then, the sequence of measuring an average value of the emission current according to a voltage of a rectangular waveform having 32 consecutive pulses is carried out at an interval of 2 seconds, whereby a deviation and an average value thereof per 30 minutes are calculated. Here, note that in comparing the magnitudes of fluctuations among the plurality of electron-emitting devices, the peak values of the applied voltages are set so that the above-mentioned average values of the currents generally become equal to one another.

As materials for the cathode electrode 2 and the gate electrode 8A, there can be used metals such as for example Be, Mg, Ti, Zr, Hf, V, Nb, Ta, Mo, W, Al, Cu, Ni, Cr, Au, Pt, and Pd, or alloys of these metals. In addition, carbides such as TiC, ZrC, HfC, TaC, SiC, WC, etc., borides such as HfB₂, ZrB₂, LaB₆, CeB₆, YB₄, GdB₄, etc., nitrides such as TiN, ZrN, HfN, etc., semiconductors such as Si, Ge, etc., and so on can be used.

As materials for the electron emission structure 3, any metal can be used, but in particular, metals of high melting points are preferable. As the high melting point metals, molybdenum and tungsten can be preferably used.

As stated above, the electron-emitting device to which the manufacturing method of this embodiment can applied is an electron-emitting device that applies a voltage between a first electrode (cathode electrode) and a second electrode (gate electrode) which is arranged away from the first electrode, so that electrons are emitted from a first electrode side under the effect of an electric field. Here, note that in cases where electrons are irradiated from the electron-emitting device to an electrode other than the gate electrode, an anode electrode is arranged apart from the substrate 1, and an electric potential sufficiently higher than an electric potential applied to the gate electrode 8A is applied to the anode electrode. By doing in this manner, electrons pulled out by the gate electrode 8A (electrons emitted under the action of an electric field) are irradiated to the anode electrode. Such an electron emission apparatus becomes a three-terminal (cathode electrode, gate electrode, anode electrode) structure. The distance between the anode electrode and the substrate 1 is set to be sufficiently larger than the distance between the cathode electrode 2 and the gate electrode 8A, and is typically set to a value ranging from 500 μm to 2 mm. In the case of using this electron-emitting device as an electron source of an image display device (electron beam display), the anode electrode is formed on a luminous body such as a fluorescent body. By irradiating the luminous body with the electrons emitted from the electron-emitting device, luminescence is obtained and an image is formed.

### EXAMPLES

Hereinafter, more specific examples will be described.

### First Example

A lanthanum hexaboride target 105 of a circular shape having a diameter of 8 inches and a Si-wafer substrate 102 were used, and the substrate 102 and the target 105 were arranged in opposition to each other, as shown in FIG. 1. An erosion region 104 was formed at a position spaced by a distance of 60 mm from the center of the target. A shield plate 200 is arranged vertically above the target 105, and a mask of an entire erosion opposed region of the substrate 102 was masked. In addition, the shield plate 200 has an opening portion 201 arranged above the central portion of the target 105. A distance L1 between the substrate 102 and the target 105 was set to 90 mm, and a distance L2 between the shield plate 200 and the target 105 was set to 70 mm. The degree of vacuum at the time of exhausting under high vacuum was set to 2×10⁻⁴ Pa.

By using a convergence type magnet having a magnetic field of 1,000 G as a magnet 107, a plasma density distribution 202 was formed in such a manner that the plasma density in the opening portion 201 becomes higher than that in its peripheral region. The value, which is obtained by dividing the discharge power of an RF power supply by the area of the target, was set to 1.54 W/cm². In addition, an argon (Ar) gas was used as a sputtering gas, and the pressure of the argon gas was set to 1.5 Pa. Then, a lanthanum boride film was deposited on the substrate 102 while moving the substrate 102 in an arrow direction of FIG. 1.

### First Comparative Example

A lanthanum boride film of a first comparative example was formed by means of the same method as the first example except for using a divergence type magnet having a magnetic field 1,000 G instead of the convergence type magnet. In the first comparative example, a plasma density in an opening portion 201 was lower than that in its peripheral region.

The lanthanum boride films obtained according to the first example and the first comparative example were individually analyzed by means of an X-ray diffraction method. For the film of the first example, the FWHM of a diffraction peak on a (100) surface was 0.55 degrees, and a value obtained by dividing the integral value of the diffraction peak on the (100) surface by the integral value of a diffraction peak of a (110) surface was 3.3. On the other hand, for the film of the first comparative example, the FWHM of a diffraction peak on a (100) surface was 0.80 degrees, and a value obtained by dividing the integral value of the diffraction peak on the (100) surface by the integral value of a diffraction peak on a (110) surface was 1.7. That is, the first example was able to obtain the film of higher crystallinity oriented to the (100) surface than that of the first comparative example.

### Second Example

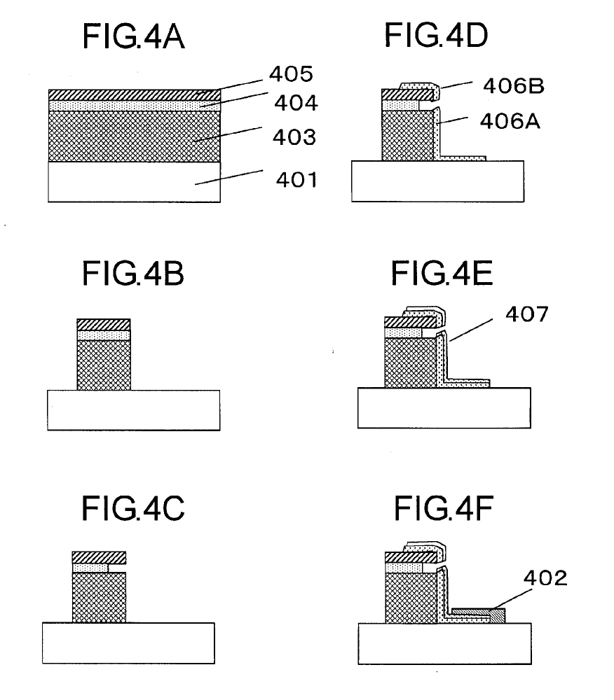

A manufacturing method of an electron-emitting device according to a second example will be described with reference to FIG. 4A-FIG. 4F. FIG. 4A-FIG. 4F are diagrammatic illustrations sequentially showing the manufacturing steps of the electron-emitting device.

A substrate 401 is a substrate for supporting an element in a mechanical manner. In this example, a PD 200, which is a low sodium glass developed for plasma displays, was used as the substrate 401.

First, as shown in FIG. 4A, insulating layers 403, 404 and a conductive layer 405 were laminated on the substrate 401. The insulating layers 403, 404 are insulating films, respectively, which are made of materials which are excellent in processability. In the second example, the insulating layer 403 of silicon nitride (SiₓN_{y}) having of a film thickness 500 nm and the insulating layer 404 of silicon oxide (SiO₂) having a film thickness of 30 nm were formed by means of a sputtering method. In addition, the conductive layer 405 of tantalum nitride (TaN) having a thickness of 30 nm was formed also by the sputtering method.

Then, a resist pattern was formed on the conductive layer 405 by means of a photolithography technology, after which the conductive layer 405, the insulating layer 404 and the insulating layer 403 were processed in this order by the use of a dry etching technique (see FIG. 4B). A CF₄ type gas was used as a process gas at this time. As a result of having performed RIE (Reactive Ion Etching) using this gas, the angle of a side surface (inclined surface) of the insulating layer 403 was about 80 degrees with respect to a horizontal surface of the substrate.

After exfoliating the resist, using a mixed solution of ammonium fluoride and fluoric acid, which is called buffered fluoric acid (BHF), the insulating layer 404 was etched to form a concave portion (recess portion) (see FIG. 4C).

As shown in FIG. 4D, molybdenum (Mo) was made to adhere on the side surface and an upper surface (an inner surface of the concave portion) of the insulating layer 403, whereby an electron emission structure (conductive film) 406A was formed. Here, note that at this time, a molybdenum layer 406B was adhered also on the conductive layer 405 (gate electrode). In this example, an EB vapor deposition method was used as a deposition method.

Subsequently, as shown in FIG. 4E, a lanthanum hexaboride film 407 was formed on the electron emission structure 406A. The lanthanum hexaboride film 407 was formed by means of the same method as the first example. That is, at the time of sputtering the lanthanum hexaboride film, the value, which is obtained by dividing the discharge power of an RF power supply by the area of a target, was set to 1.54 W/cm², and the pressure P of an Ar gas was set to 1.5 Pa. A shield plate was arranged above the target, and an entire erosion opposed region was masked. A distance L1 between the substrate and the target was set to 90 mm, and a distance L2 between the shield plate and the target was set to 70 mm. By a convergence type magnet having a magnetic field of 1,000 G, a plasma density distribution was formed in such a manner that the plasma density in the opening portion becomes higher than that in its peripheral region. Then, the substrate with the structure as shown in FIG. 4D being formed thereon and the lanthanum hexaboride target were arranged in opposition to each other, and the lanthanum hexaboride film 407 was formed by means of a through deposition method.

Thereafter, as shown in FIG. 4F, a cathode electrode 402 was formed by means of the sputtering method. Copper (Cu) was used for the cathode electrode 402. The cathode electrode has a thickness of 500 nm.

The electron-emitting device thus formed was put in a vacuum device, and the interior of the vacuum device was exhausted up to 10⁻⁸ Pa. Then, a pulsed voltage of a rectangular waveform having a pulse width of 1 ms and a frequency of 60 Hz was repeatedly applied between the cathode electrode 402 and the gate electrode 405 in such a manner that the electric potential of the gate electrode 405 became higher than that of the cathode electrode. A gate current flowing into the gate electrode 405 was monitored, and at the same time, an anode electrode was arranged at a position spaced upwardly by a distance of 5 mm from the substrate 401, and a current (anode current) flowing into the anode electrode was also monitored, so that the variation of an anode emission current was calculated. Thus, the variation (fluctuation) of the emission current (anode current) was obtained by performing the sequence of measuring an average value of the emission current according to a voltage of a rectangular waveform having 32 consecutive pulses at an interval of 2 seconds, and calculating a deviation and an average value thereof per 30 minutes. Then, a value {(standard deviation/average value)×100(%)} of the data thus obtained was calculated.

In addition, for the purpose of a comparison, an electron-emitting device was also prepared for trial which has a lanthanum hexaboride film formed by means of the same method as the first comparative example, and the same measurements as stated above were performed.

As a result, the electron-emitting device of this example had an average of the current variation value which is 0.8 times in comparison with the electron-emitting device of the comparative example, and was able to continue good electron emission with little change of brightness over a long period of time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-018344, filed on Jan. 29, 2009, which is hereby incorporated by reference herein in its entirety.

What is claimed is:

1. A manufacturing method of a boride film, comprising the steps of:
preparing a substrate, a target of a boride, and a shield member having an opening portion; and
depositing a boride film on the substrate through the opening portion by means of a sputtering method in a state where the substrate, the target and the shield member are arranged in such a manner that the substrate and the target are arranged in opposition to each other, with the shield member being positioned between the substrate and the target,
wherein
the shield member is arranged so as to shield between an erosion region of the target and the substrate; and
a distribution of plasma density in a space between the substrate and the target is set in such a manner that a plasma density in a region in which the opening portion is located becomes higher than a plasma density in a region shielded by the shield member.

2. A manufacturing method of a boride film according to claim 1, wherein
a plasma is caused to concentrate on the region in which the opening portion is located, by using a magnetic field generation device in which a magnetic flux density in the region where the opening portion is located is higher than a magnetic flux density in the region shielded by the shield member.

3. A manufacturing method of a boride film according to claim 1, wherein
the boride is lanthanum boride.

4. A manufacturing method of an electron-emitting device provided with a boride film as an electron-emitting member, wherein
the boride film is manufactured by means of the manufacturing method of a boride film according to claim 1.

5. A manufacturing method of a boride film, comprising the steps of:
preparing a substrate, a target of a boride, and a shield member; and
depositing a boride film on the substrate through a region not shielded by the shield member by means of a sputtering method in a state where the substrate, the target and the shield member are arranged in such a manner that the substrate and the target are arranged in opposition to each other, with the shield member being arranged to shield between an erosion region of the target and the substrate,
wherein
a distribution of plasma density in a space between the substrate and the target is set in such a manner that a plasma density in the region not shielded by the shield member becomes higher than a plasma density in a region shielded by the shield member.

6. A manufacturing method of a boride film according to claim 5, wherein
a plasma is caused to concentrate on the region not shielded by the shield member, by using a magnetic field generation device in which a magnetic flux density in the region not shielded by the shield member is higher than a magnetic flux density in the region shielded by the shield member.

7. A manufacturing method of a boride film according to claim 5, wherein
the boride is lanthanum boride.

8. A manufacturing method of an electron-emitting device provided with a boride film as an electron-emitting member, wherein
the boride film is manufactured by means of the manufacturing method of a boride film according to claim 5.
